(19) United States
(12) Patent Application Publication
(10) Pub. No.: US 2022/0320476 A1
(43) Pub. Date: Oct. 6, 2022

(54) PROCESS FOR PRODUCING FLEXIBLE OLED SCREENS AND FLEXIBLE OLED SCREENS

(71) Applicant: Airbus Operations GmbH, HAMBURG (DE)

(72) Inventor: Alejandro MORALES ANTON, Shenzhen (CN)

(21) Appl. No.: 17/595,603

(22) PCT Filed: Aug. 17, 2020
(86) PCT No.: PCT/EP2020/072977

§ 371 Date: Nov. 19, 2021

Related U.S. Application Data
(60) Provisional application No. 62/908,133, filed on Sep. 30, 2019.

(51) Int. Cl. H01L 51/56; H01L 51/52; H01L 27/32

(52) U.S. Cl. CPC H01L 51/56; H01L 51/5253; H01L 27/3293; H01L 2251/566; H01L 2251/5338

(57) ABSTRACT

Processes for producing an OLED screen with a reduced, minimized, or eliminated bezel section surrounding the display are. The circuitry (206) of the display screen is moved to beneath the OLED (212) and transistor layers (210). The screens with the reduced sized may be installed in an aircraft, and, two or more of the OLED screens with reduced sized may be positioned adjacent to each other so as to form an array.

### RELATED APPLICATIONS

This application is a National Stage of International Application No. PCT/EP2020/072977 filed on Aug. 17, 2020, which claims priority to U.S. Provisional Patent Application No. 62/908,133 filed on Sep. 30, 2019.

### FIELD OF THE INVENTION

This invention relates generally to flexible organic light emitting diode (“OLED”) screens, to processes for producing such screens, and more particularly to producing such screens for an aircraft and an aircraft having such OLED screens.

### BACKGROUND OF THE INVENTION

Today's flexible OLED screen market is primarily focused on smartphones, notebooks, monitors, and home displays. Applicant has previously identified the desirability and applicability of incorporating these screens into aircraft. See, International Application No. PCT/EP2019/063848, filed on May 28, 2019, and U.S. Prov. Pat. Appl. Ser. No. 62/870,839, filed on Jul. 5, 2019, the entireties of which are incorporated herein by reference.

Specifically, it has been found that it would be beneficial to incorporate the flexible OLED screens in, for example, a lining panel, a ceiling panel, a floor panel, a hat rack, a cabin door, a compartment separation module, a window blind, a luggage compartment door, a galley sidewall, and a lavatory monument sidewall, to name a few. Generally, the benefits of using the OLED screens compared with current screens include: being lighter than rigid/glass OLED solutions; not requiring structural reinforcements; consuming far less power than current solutions (about 3 watt per display); not requiring heat dissipation; easily integrated into an aircraft cabin; and the ability to cover large areas.

However, as noted above, the current OLED screen market is focused primarily towards high volume consumer goods like smartphones, notebooks, monitors, home displays, and the like. Accordingly, due to the high costs associated with setting up manufacturing lines for OLED screens, the flexible OLED screens currently being produced are sized for these consumer products and mostly have a rectangular shape. While these sizes and shapes are acceptable for the various listed consumer goods, it is believed that the sizes and shapes of these screens are not optimally suitable for use in aircraft environments.

For example, while it is known to arrange two or more screens into an array to provide a display surface with an increased surface size compared to just one screen, the current OLED screens have bezels that are too large for use in an aircraft environment when arranged in a multiple panel array. More specifically, the currently produced OLED screens have bezels that are in the range of four to seven mm. Thus, the crosses or bands formed by adjacent bezels are too wide when the screens are placed adjacent to one another.

The main function of the bezels is to cover the electronic circuits controlling the pixels of the OLED screen. The bezels also function to protect the OLED display from the penetration of moisture and oxygen (that will damage the organic content in the materials forming the OLED screen).

Moreover, even though these OLED screens are being produced for the consumer products, due to the nature of the production processes, it is not a simple task to use existing production lines to produce differently sized screens. Thus, while there is some demand for the OLED screens with the appropriate size and shape for an aircraft environment, the demand does not out weight the high cost of establishing or setting up a new production line for appropriately sized and shaped OLED screens for aircraft. According to current estimates, the cost of setting up one production line for an OLED screen with one specific size is believed to be about $50 million. Thus, due to the different sizes and shapes needed and the relatively low production output expected, it is not currently economically feasible to merely set up new production lines to make the OLED screens for an aircraft environment without adjustments to the design of the screens so that they are better able to be utilized in an aircraft environment.

Accordingly, it would be desirable to have effective and efficient processes for the production of OLED screens that are more suited for use in an aircraft environment.

### SUMMARY OF THE INVENTION

The present invention is directed at solving one or more of these problems by providing a process for producing OLED screens and OLED screens produced by such a method which can be installed in an aircraft.

The present applicant has recently proposed processes for producing OLED screens for aircraft from production OLED screens that providing the OLED screen with a configuration that is more suitable to be utilized in an array configuration by cutting off a portion of the bezel. These processes are described in U.S. Prov. Pat. Appl. Ser. No. 62/870,839 (filed on Jul. 5, 2019).

The present invention, however, provides a new process for producing the OLED screens by reducing, preferably minimizing, and most preferably eliminating the bezels. According to the present invention, the electronic circuits that control each of the pixels are located behind the thin film transistors layer (or TFT) of the OLED screen. Thus, by moving the location of the control circuitry, the bezels of the screen, if present, are smaller, compared with conventional screens. This allows the screens to be used in an array without the adjacent bezels creating as large as an undesirable visual impression.

Current flexible OLED screens are manufactured using a Chemical Vapor Deposition (“CVD”) process. Briefly, as is known, this process places a pre-heated plastic substrate into a vacuum chamber and injects gas molecules into the chamber. Within the chamber the gaseous molecules are deposited on the substrate and form the different layers of the flexible OLED screens. The gaseous molecules have different electrical properties, so they can be part of the transistors layers, OLED layers, or encapsulation layers. The thin film transistors layer (or TFT) is the layer of the display screen that functions to trigger the individual OLED pixels. The signal for triggering the pixels arrives to the transistors from the control circuits placed on the perimeter of the display screen, underneath the bezels. The borders, or bezels, cannot display any image. Accordingly, in the present application, this control circuitry has been moved to allow for the size of the bezels to be reduced, minimized, or even eliminated.

Therefore, in some aspects the present invention may be characterized broadly as providing an OLED screen comprising: a display area formed from a plurality layers, the plurality of layers including an OLED layer, a transistor layer, and a circuitry layer, wherein the circuitry layer is disposed on a first side of the transistor layer, and wherein the OLED layer is disposed on a second side of the transistor layer, the second side opposite the first side. The OLED screen may further comprise an encapsulation layer disposed on the OLED layer. The OLED screen may further comprise a substrate disposed on the circuitry layer.

In one or more aspects, the present invention may also be characterized as providing an array comprising at least two OLED screens as described here.

In still further aspects, the present invention may also be characterized as providing a process of making an OLED screen by: depositing a transistor layer on a circuitry layer; and, depositing an OLED layer on the transistor layer such that the OLED layer and the circuitry layer are on opposite sides of the transistor layer. The process may further include encapsulating the OLED layer. The circuitry layer may be disposed on a supporting substrate.

In yet another aspect, the present invention may also be characterized as providing a process of forming an array by: arranging two or more OLED screens produced according of to the present disclosure adjacently so as to form an array.

In at least one or more aspects, the present invention may also be characterized as providing an aircraft comprising an OLED screen as described here or an array as described here.

These aspects, described in more detail below and in the attached drawings, are believed to provide advantages over the current state of the art, allowing for the effective and efficient production of OLED screens for an aircraft or other environment. These and other benefits will be appreciated by those of skill in art in view of the present disclosure.

### DETAILED DESCRIPTION OF THE DRAWINGS

One or more exemplary embodiments of the present invention will be described below in conjunction with the following drawing figure, in which:

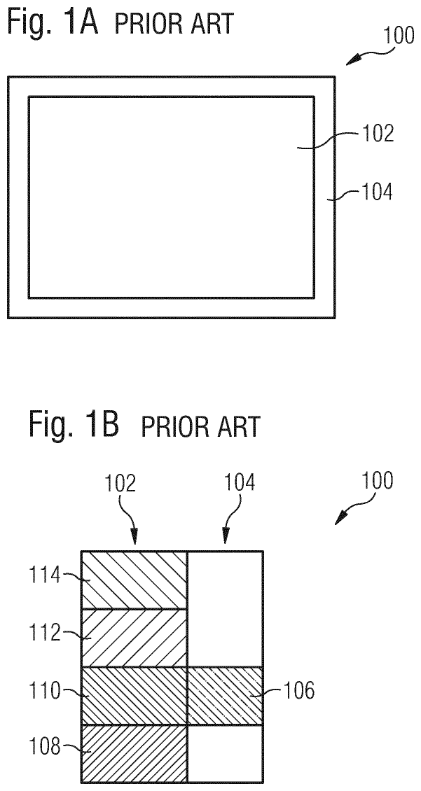

FIG. 1A depicts a front view of a conventional OLED screen;

FIG. 1B depicts a side, cutaway view of the conventional OLED screen shown in FIG. 1A;

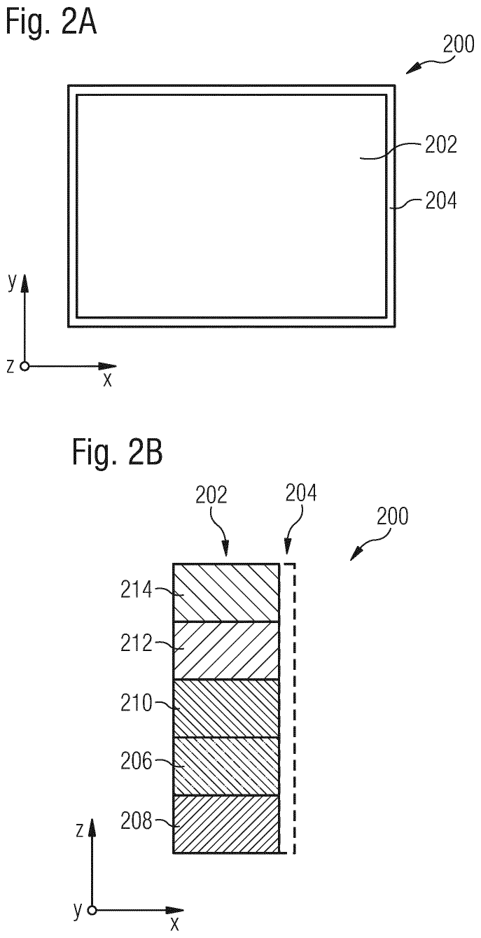

FIG. 2A depicts a front view of an OLED display screen according to one or more aspects of the present invention;

FIG. 2B depicts a side, cutaway view of the OLED display screen shown in FIG. 2A;

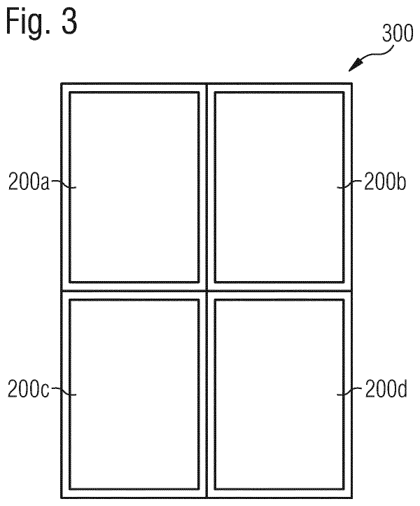

FIG. 3 shows an array with multiple OLED screens produced according to one or more aspects of the present invention; and,

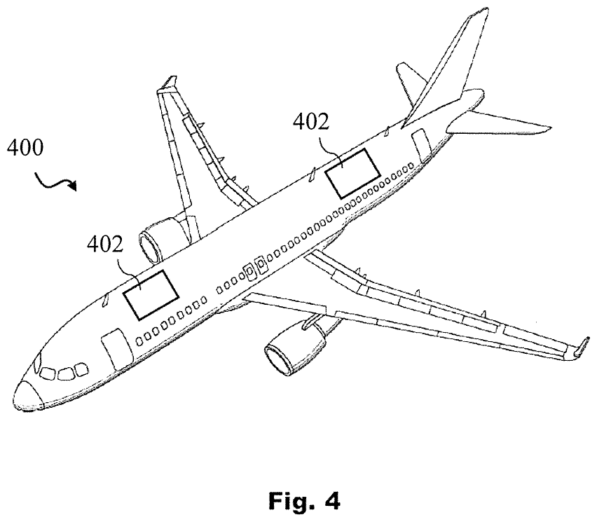

FIG. 4 shows an airplane with multiple OLED screens therein.

### DETAILED DESCRIPTION OF THE INVENTION

As noted above, the present invention provides OLED screens that are more readily adapted to use in an aircraft environment compared with production OLED screens that are designed for consumer goods. The processes of the present invention provide OLED screens in which the control circuitry is located underneath the OLED and the TFT layers. Thus, the screens produced according to the present processes have reduced, minimized, or eliminated bezels (compared with conventional OLED screens). This facilitates that use of the screens in an array with less area inside the combined display taken up by the adjacent bezels.

With these above general aspects of the present invention in mind, one or more embodiments of the present invention will be described with the understanding that the following description is not intended to be limiting.

As shown in FIGS. 1A and 1B, a current OLED display screen 100 includes a display area 102 surrounded by a bezel 104 at the perimeter of the display area 102. As discussed above, beneath the bezel 104 is control circuitry 106 for providing a signal to the pixels of the display area 102. The display area 102 is formed from a plurality of layers which includes, a lower substrate layer 108, a thin film transistors layer 110, an OLED layer 112, and an encapsulation layer 114. The substrate layer 108 is used to produce the OLED display screen 100 and provide some protection and structural integrity to the OLED display screen 100. The thin film transistors layer 110 is used to transmit signals from the circuitry 106 to the individual pixels in the OLED layer 112 so that the pixel produces the desired visual effect. The encapsulation layer 114 protects the OLED layer 112.

Turning to FIGS. 2A and 2B, an OLED display screen 200 according to the present invention also includes a display area 202. It is contempered that the OLED display screen 200 only include the display area 202, but, it may also include a bezel 204 at the perimeter of the display area 202. The bezel 204 is reduced in sized compared with the bezel 104 of the current OLED display screen 100 (FIGS. 1A and 1B).

As can be seen in FIG. 2B, in the OLED display screen 200 according to the present invention, control circuitry 206 has been moved from the bezel 204 to the display area 202. Thus, the OLED display screen 200 includes a lower substrate layer 208, the control circuitry 206 disposed on the substrate layer 208, a thin film transistors layer 210 disposed on the control circuitry 206, an OLED layer 212 above the thin film transistors layer 210, and an encapsulation layer 214 on top of the OLED layer 212. The use of “above,” “on top” and other similar language is meant in relation to the orientation shown in the drawing.

Thus, on one side of the thin film transistors layer 210 is the OLED layer 212, while on the opposite side of the thin film transistors layer 210 is the control circuitry or circuit layer 206. Accordingly, in the OLED display screen 200 according to the present invention, rather than connecting the pixel driving circuits 206 to the transistors layer 210 in a horizontal plane (as shown in FIG. 1B), the present invention proposes a connection between the two in a vertical plane.

In order to manufacture the OLED display screen 200, the circuit layer 206 will be the first layer to be deposited on the substrate 208. Above the circuit layer 206, the TFT layer 210 will be deposited with their already existing fine-masks. The TFT layer 210 will also include spaces on these fine-masks so the conductive molecules can be deposited layer by layer, to form the vertical connections needed. Alternatively, a different manufacturing approach could be to leave holes in every TFT layer and fulfil/deposit the conductive molecules within the holes once the latest TFT layer has been deposit. Once the TFT layer 210 has been deposited, the OLED layer 212 and encapsulation layers 214 can be applied to form the OLED display screen 200.

As noted above, such an OLED display screen 200 will have reduced, minimized, or eliminated bezels 204.

While the OLED display screen 200 may be used alone, with the reduced, minimized, or eliminated bezels 204, it is contemplated that an array 300 is formed, as shown in FIG. 3 by combining two or more of the OLED display screens 200. The array 300 is depicted as having four screens 200a, 200b, 200c, 200d; however, any number of screens could be used. In the array 300, the space taken up by the bezels 204 (see FIG. 2A) within the combined display area is smaller than had the same array been formed with the OLED screens 100 with the conventionally sized bezels 104.

Whether arranged in an array, or used alone, the present processes are believed to provide OLED screens, which, for example, can be used within an aircraft environment. For example, as shown in FIG. 4, an aircraft 400 includes two OLED screens 402.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. An OLED screen comprising:
a display area formed from a plurality of layers, the plurality of layers including an OLED layer, a transistor layer, and a circuitry layer,
wherein the circuitry layer is disposed on a first side of the transistor layer, and
wherein the OLED layer is disposed on a second side of the transistor layer, the second side opposite the first side.

2. The OLED screen of claim 1, further comprising an encapsulation layer disposed on the OLED layer.

3. The OLED screen of claim 1, further comprising a substrate disposed on the circuitry layer.

4. The OLED screen of claim 1, wherein the screen is adjacent to a second screen so as to form an array, the second screen comprising
a display area formed from a plurality of layers, the plurality of layers including an OLED layer, a transistor laver, and a circuitry layer,
wherein the circuitry layer is disposed on a first side of the transistor layer, and
wherein the OLED layer is disposed on a second side of the transistor layer, the second side opposite the first side.

5. The OLED screen of claim 4, wherein the array is disposed in an aircraft.

6. A process of making an OLED screen comprising:
depositing a transistor layer on a circuitry layer; and,
depositing an OLED layer on the transistor layer such that the OLED layer and the circuitry layer are on opposite sides of the transistor layer.

7. The process of claim 6, further comprising encapsulating the OLED layer.

8. The process of claim 6, wherein the circuitry layer is disposed on a supporting substrate.

9. The process of claim 6 further comprising:
forming an array by adjacently arranging two or more of the OLED screens.

10. The process of claim 9, wherein the array is disposed in an aircraft.
